(19) United States
(12) Patent Application Publication
(10) Pub. No.: US 2015/0366093 A1
(43) Pub. Date: Dec. 17, 2015

(54) Case For Portable Electronic Device With Integral Detachable Power Converter And USB Connector

(71) Applicant: BBD Technologies, LLC, Williamsville, NY (US)

(72) Inventors: Matthew Battista, Williamsville, NY (US); Gregory S. Deal, Canandaigua, NY (US)

(21) Appl. No.: 14/741,032

(22) Filed: Jun. 16, 2015

Related U.S. Application Data
(60) Provisional application No. 62/012,940, filed on Jun. 16, 2014.

(51) Int. Cl. H05K 5/02; H02J 7/00; H02M 7/04

(52) U.S. Cl. CPC H05K 5/0247; H05K 5/0217; H02M 7/04; H02J 7/0052; H02J 2007/0062

(57) ABSTRACT

A case for portable electronic devices is disclosed, providing physical protection from abrasion and mishandling and also including an integral power conversion module with integral ac power mains blades and a USB connector and small form factor. The power conversion module with integral USB connector is provided to recharge the internal batteries of the portable electronic device and is stored within the outline envelope of the case when not in use. The power conversion module is removable from the case for connection to a wall power receptacle or a mating USB connector on another device, and is connected to the case by a retractable cord. The power conversion module ac power mains blades are retractable to minimize the overall volume when stored within the case envelope.

### CROSS-REFERENCE TO RELATED APPLICATIONS

This application claims priority to and the benefit under 35 U.S.C. 119(e) of U.S. Provisional Application No. 62/012,940 filed on Jun. 16, 2014. The entire contents of said Provisional Application No. 62/012,940 are hereby incorporated by this reference as if fully set forth herein.

### BACKGROUND

1. Field

The present invention relates to accessories for portable electronic devices, and more particularly relates to power converter apparatus for charging the batteries of portable electronic devices. The invention further relates to protective cases for portable electronic devices. The invention also relates to accessories used to interconnect portable electronic devices that utilize the Universal Serial Bus (USB) protocols and standards for serial data communication.

2. Description of the Prior Art

By way of background, portable electronic devices have become ubiquitous and now find wide usage by almost all individuals, not only in the developed world but also in emerging nations. These devices include cellular telephones, personal digital assistants, music players, portable computers, and so on. Almost without exception, portable electronic devices are powered by electrochemical cells (batteries), with the majority of these being secondary cells that are rechargeable. Such devices therefore need a suitable source of electrical energy to periodically recharge the batteries. The recharging energy is typically provided from a utility mains source such as 120 Vac/60 Hz power in the United States or 230 Vac/50 Hz power on the European continent. Electronic circuitry is used to convert the high ac voltage to a low dc voltage suitable for recharging the batteries in the device. For the many devices that do not integrate this recharging circuitry into the device, the user must have access to a separate charging device and interconnecting cable that are cumbersome to carry.

In addition to the requirement for periodic recharging of internal batteries, many portable electronic devices are equipped with an interface that complies with the Universal Serial Bus Specification (Revision 2.0 released Apr. 27, 2000). This interface defines physical and electrical parameters required to connect and control the exchange of dc energy and serial digital data. The inclusion of a USB interface on portable electronic devices provides the capability to exchange digital data such as files containing audio and/or image information as well as dc voltage for powering circuitry and/or charging internal batteries.

The requirement for providing a reliable source of power and conveniently recharging the batteries of portable electronic devices is typically met by the use of a portable power converter module. The power converter usually comes with an ac power cord that plugs into an ac mains power source, and a dc power cable that interconnects the power converter to the portable electronic device to be charged. The dc power cable is in many cases a USB interface cable fitted with appropriate connectors. The dc power cable may thus also satisfy the requirement for interconnecting portable devices via a USB interface.

It will be appreciated in view of the foregoing that in order to provide a portable electronic device with both charging capability and a data connection via USB, at least two separate accessories must be procured and maintained, one being a separate power converter module and other being a USB interface cable.

### SUMMARY

The foregoing problems are solved and an advance in the art is provided by a novel accessory protective case for portable electronic devices that includes integral power conversion circuitry with a small form factor enabled by a unique implementation of retractable ac power plug blades and a power cord attachment carrying dc power. Respectively integrated with the power conversion circuitry and power cord is a retractable USB connector and associated serial data wiring to support connection of the device to other USB enabled devices without the need to remove the case or to supply a separate USB cable. The device case includes a conformal covering case shell configured to encompass all or a portion of a portable electronic device.

In one aspect of the invention, the device case includes a small power conversion module that is detachable from the device case during use and which may be stored in a module holder cavity in the rear of the device case when not in use. In another aspect of the invention, the device case includes a power cord reel with an electrical slip ring so that the power cord connecting the power conversion module to the case may be quickly and easily retracted into the case. In yet another aspect of the invention, a pair of ac power mains plug blades on the power conversion module can rotate and retract into the housing envelope of the conversion module when not in use, thereby reducing the conversion module thickness. In yet another aspect of the invention, the power conversion module has a hinged connection for the dc power cord, so that the cord may be rotated relative to the power conversion housing when transitioning between storage and deployment to minimize the thickness of the power conversion module. In yet another aspect of the invention, the connection between the case and the portable electronic device through which dc power and serial data flows may be temporarily disconnected without removing the case in order to connect the electronic device to other equipment.

It is therefore an object of the invention to provide a protective case for a portable electronic device that includes a small power conversion module and a retractable power/data cord with a low-profile form factor.

A further object of the invention is to provide a protective case for a portable electronic device case that includes a detachable power conversion module that may be connected to a wall receptacle for ac mains power or to another USB-equipped device and allow the portable electronic device to be manipulated and used while connected to the wall receptacle or other USB-equipped device for powering or internal battery recharging (and for data transfer in the case of a USB connection). The device case may be fitted with an integral cord reel or spool equipped with an electrical slip ring to permit extension and retraction of the power/data cord by means of reel rotation.

A still further object of the invention is to provide a power conversion module with a unique implementation of ac power mains plug blades that may rotate and retract into the module case when not in use in order to minimize the power conversion module case thickness.

A still further object of the invention is to provide a power conversion module with a hinged connection for a captive cord, so that the cord may be rotated about the power conversion module case when transitioning between storage and deployment to minimize the power conversion module thickness.

### BRIEF DESCRIPTION OF THE DRAWINGS

The foregoing and other features and advantages will be apparent from the following more particular description of example embodiments, as illustrated in the accompanying Drawings, in which:

FIG. 1 is a plan view of the rear of an exemplary embodiment of the present invention when attached to a representative portable electronic device;

FIG. 2 is a plan view of the rear of an exemplary embodiment of the present invention with the power conversion module removed from a module holder cavity of the case for insertion into an ac mains wall receptacle, and with the dc power cord unfolded and the ac power mains plug blades extended;

FIG. 3 is a plan view of the power conversion module configured for stowing in the case, with the dc power cord folded beneath the module and the ac mains plug blades and USB connector retracted;

FIG. 4 is an elevation end view of the power conversion module with the ac mains plug blades and USB connector refracted; and

FIG. 5 is a plan view of the power conversion module removed from the module holder cavity and configured for connection of the USB connector to a mating USB connector on another device, with the ac mains plug blades retracted and the USB connector extended.

### DETAILED DESCRIPTION OF EXAMPLE EMBODIMENTS

### Introduction

An exemplary portable electronic device case with an integral power conversion module for providing power and charging the batteries of a portable electronic device will now be described, together with design aspects for a power conversion module with minimum volume and maximum ease of use. The device case is usable as an accessory protective case for a wide variety of portable electronic devices, including but not limited to cellular telephones, personal digital assistants, music players, portable computers, etc. Disclosed embodiments of the device case are characterized by a low-profile form factor and inclusion of all components/assemblies needed to provide power and recharge the internal batteries of a portable electronic device from ac mains power or a USB receptacle (and also facilitate data transfer), while allowing the device to be manipulated and used.

### Illustrated Embodiments

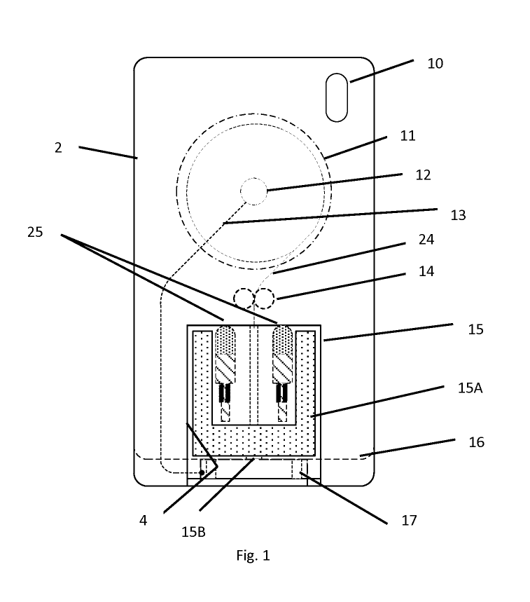

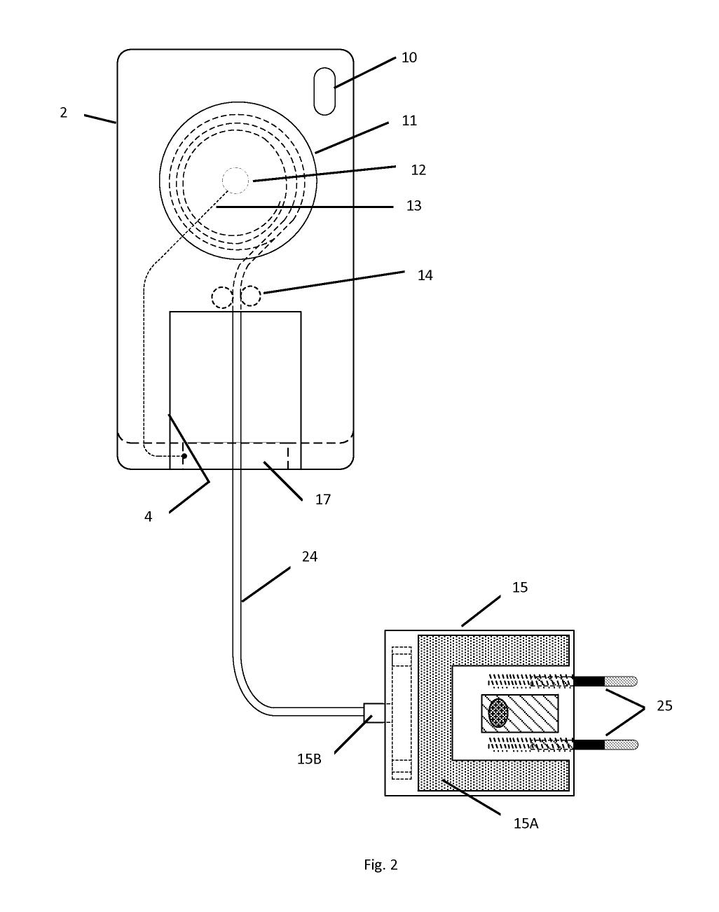

Turning now to the Drawings, wherein like reference numerals signify like elements in all of the several views, FIGS. 1 and 2 are plan views of the rear of an accessory protective case 2 when installed on a representative portable electronic device 16, such as a cellular telephone. The case 2 is constructed to encompass the entire periphery of the device 16, and is retained by captivating the front edge of the device or an intermediate edge or device feature. The case 2 may include holes or cutouts 10 for access of device surface features such as cameras, headphone jacks and speakers. These access holes may be on the back or any edge surface of the case 2. A captive electrical cord 24 carrying dc power for the case 2 is wound on a reel or spool 11.

The cord reel 11 may have one face flush on the rear face of the case so that it may be manually wound to retract the cord 24. Alternatively, the cord reel 11 may be biased to apply assisting torque to allow assisted retraction of the cord 24. One example biasing mechanism would be a rewind spring or a rewind spring/ratchet mechanism. The cord reel 11 may be equipped with a multi-circuit electrical slip ring 12. The slip ring 12 includes a wiper portion that maintains an electrical connection between the captive end of the cord 24 and an internal circuit 13, while allowing the reel to rotate. The internal circuit 13 carries electrical energy from the cord 4 to a detachable interface connector 17 for the device 16. The case 2 may also be equipped with rollers 14 to guide the cord 24 on and off the reel as it is extended and retracted to minimize the likelihood of jamming.

Near one edge of the case 2, an integral detachable power conversion module 15 is housed within a module holder cavity 4 of the case when not in use. The power conversion module 15 includes internal circuitry 15A for converting ac mains power to dc power at a voltage suitable for charging the device 16. The power conversion module 15 has a small form factor enabled by a unique implementation of retractable ac mains power plug blades 25 and a hinged power cord attachment 15B for the cord 24. The power conversion module 15 allows the case 2 to be connected to a wall receptacle for ac mains power so that the device 16 can be manipulated and used while connected to the wall receptacle for powering or internal battery recharging. The hinged power cord attachment 15B allows the cord 24 to be rotated about the power conversion module 15 through an angle of at least 180 degrees when transitioning between storage and deployment to minimize the module's thickness.

In FIG. 1, the case 2 is shown with the power conversion module 15 in its stowed position within the cavity 4. The power plug blades are retracted and rotated 90 degrees from the normal operational position they would otherwise be in when plugged into a standard NEMA 5-15R ac mains power receptacle. In FIG. 2, the case 2 is shown with the power conversion module 15 removed from its stowed position within the cavity 4. The cord 24 that is captivated to the power conversion module 15 by the hinged power cord attachment 15A is extended from the reel 11. The ac mains power plug blades 25 are shown to be extended and rotated to their normal operational position as required to mate with a standard NEMA 5-15R ac power mains receptacle. The blades 25 may be biased to the extended position by springs or the like.

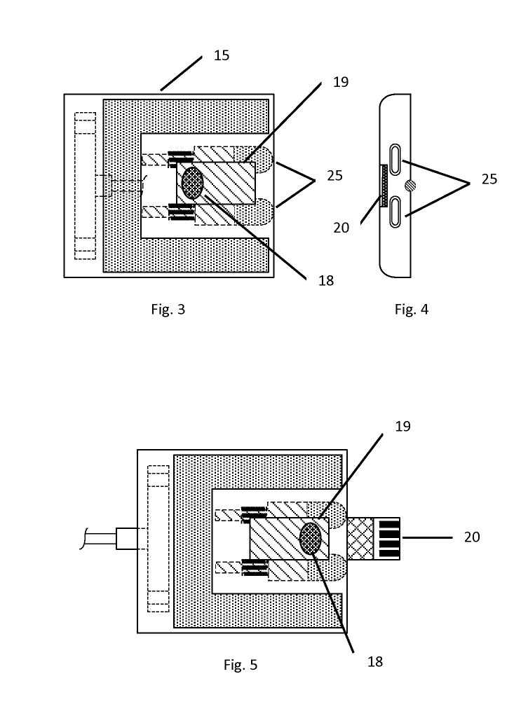

As will now be described in connection with FIGS. 3-5, there is respectively integrated with the power conversion module 15 and the cord 24 a retractable USB connector 20 and associated serial data wiring to support connection of the device 16 to another USB-compatible device (not shown). The USB connector 20 may be configured as a USB plug or a USB receptacle according to any desired USB form factor. By way of example only, the USB connector 20 in the illustrated embodiment is configured as a USB type A plug. It allows the device 16 to connect to other USB-equipped devices without the need to remove the case 2 or supply a separate USB cable. The cord 24 may integrate USB serial data wiring. It may thus be embodied as a combined power/data cord that carries dc power and data between the power conversion module 15 and the internal circuit 13. The internal circuit 13, in turn, carries dc power and may also include serial data wiring in order to carry both dc power and data between the power/data cord 24 and the interface connector 17 for the device 16.

The USB connector 20 may be mounted to the power conversion module 15 in any desired manner. In the illustrated embodiment of FIGS. 3-5, the power conversion module 15 is shown to include a recessed sliding mechanism 19 to which the USB connector 20 is operably connected, preferably integrally therewith. The sliding mechanism 19 may be located slightly below the power module's enclosure surface and provided with a surface feature to facilitate actuation of the mechanism by a finger or thumb, such as a textured depression 18.

FIGS. 3-5 show the ac power mains blades 25 in phantom view as they are retracted into the envelope of the power conversion module 15 for storage. FIG. 4 shows that the ac mains power plug blades 25 are rotated 90 degrees from their normal operational position when in the retracted stowed position. It should be apparent to those practicing the art that each of the plug blades 25 could be easily replaced by a cylindrical connector pin as is found on an ac mains plug such as the CEE 7/16 that is used widely throughout Europe. FIG. 4 also shows the mating face of the USB connector 20. In FIG. 5, the USB connector 20 is deployed for insertion into a USB receptacle by extending the sliding mechanism 19 using the textured depression 18.

Accordingly, an auxiliary protective case for a portable electronic device with an integral detachable power converter and USB connector has been disclosed. Although example embodiments have been shown and described, it should be apparent that many variations and alternative embodiments could be implemented in accordance with the present disclosure. It is understood, therefore, that the invention is not to be in any way limited except in accordance with the spirit of the appended claims and their equivalents.

What is claimed is:

1. A protective case for portable electronic devices, comprising:
a conformal covering case shell configured to encompass all or a portion of a portable electronic device;
a detachable power conversion module that implements ac-to-dc conversion circuitry in order to develop a lower dc voltage for powering and recharging said portable electronic device from a higher ac input voltage;
a USB connector mounted on said power conversion module;
a rotatable power cord reel operable to wind and unwind a captive dc power cord that provides an electrical connection between said power conversion module and said USB connector and an internal circuit of said case shell; and
an interface connector electrically connected to said internal circuit and configured to mate with a receptacle on said portable electronic device in order to deliver dc current for powering and recharging said portable electronic device.

2. A protective case in accordance with claim 1, wherein said USB connector comprises a USB plug.

3. A protective case in accordance with claim 2, wherein said USB plug comprises a USB Type A plug.

4. A protective case in accordance with claim 1, wherein said USB connector is slidably mounted on said power conversion module for positioning between an extended position wherein said USB connector extends outside a housing envelope of said power conversion module and a retracted position in which said USB connector is retracted within said housing envelope.

5. A protective case in accordance with claim 4, wherein said USB connector is attached to a sliding mechanism on said power conversion module.

6. A protective case in accordance with claim 5, wherein said USB sliding mechanism includes a surface feature to facilitate actuation of the mechanism by a finger or thumb.

7. A protective case in accordance with claim 6, wherein said surface feature comprises a textured depression.

8. A protective case in accordance with claim 1, wherein said dc power cord comprises USB serial data wiring, such that it constitutes a power/data cord that facilitates both power and data transfer between said USB connector and said internal circuit, and wherein said internal circuit comprises serial data wiring that facilitates both power and data transfer between said internal circuit and said device.

9. A protective case in accordance with claim 1, wherein said power conversion module is housed within a module holder cavity of said case shell when not in use.

10. A protective case in accordance with claim 9, wherein said power conversion module is detachable by way of being released and removed from a cavity in said module holder and separated from said case shell while unwinding said captive dc power cord from said power cord reel.

11. A protective case in accordance with claim 1, wherein said power conversion module includes movable electrical power plug connectors that are positionable between an extended position in which said power plug connectors extend outside a housing envelope of said power conversion module and a retracted position in which said power plug connectors are retracted within said housing envelope.

12. A protective case in accordance with claim 11, wherein said power plug connectors comprise power plug blades conforming to the North American NEMA 1-15P plug standard.

13. A protective case in accordance with claim 12, wherein said power plug blades are rotatable between a first orientation when in said extended position and a second orientation when in said retracted position.

14. A protective case in accordance with claim 1, wherein said ac-to-dc conversion circuitry of said power conversion module is operable with input voltages over the range of 110-240 volts ac and input frequencies over the range of 47-63 Hz.

15. A protective case in accordance with claim 1, wherein said power cord reel includes an electrical slip ring to maintain electrical contact between said dc power cord and said internal circuit throughout a range of rotation of said power cord reel.

16. A protective case in accordance with claim 1, wherein said power cord reel either has a portion thereof that is exposed on a surface of said case shell so that said power cord reel may be manually rotated by means of finger pressure to extend and retract said dc power cord, or is biased to apply assisting torque to said power cord reel for retracting said dc power cord.

17. A protective case in accordance with claim 1, wherein said case shell is fitted with guide rollers spaced from said power cord reel to guide said dc power cord on to and off of said power cord reel during extension and retraction of said dc power cord.

18. In combination, a protective case and a portable electronic device, said combination comprising:
a portable electronic device;
a conformal covering case shell encompassing all or a portion of said portable electronic device;
a detachable power conversion module that implements ac-to-dc conversion circuitry in order to develop a lower dc voltage for powering and recharging said portable electronic device from a higher ac input voltage;
a USB connector mounted on said power conversion module;
a rotatable power cord reel operable to wind and unwind a captive dc power cord that provides an electrical connection between said power conversion module and said USB connector and an internal circuit of said case shell; and
an interface connector electrically connected to said internal circuit and configured to mate with a receptacle on said portable electronic device in order to deliver dc current for powering and recharging said portable electronic device.

19. A combination in accordance with claim 18, wherein said USB connector is slidably mounted for extension from and retraction into said power conversion module, said power conversion module further including ac power mains plugs that are slidably mounted for extension and retraction independently of said USB connector.

20. A protective case for portable electronic devices, comprising:
a detachable power conversion module that implements ac-to-dc conversion circuitry in order to develop a lower dc voltage for powering and recharging said portable electronic device from a higher ac input voltage;
a USB connector mounted on said power conversion module;
a rotatable power cord reel operable to wind and unwind a captive dc power cord that provides an electrical connection between said power conversion module and said USB connector and an internal circuit of said case shell;
an interface connector electrically connected to said internal circuit and configured to mate with a receptacle on said portable electronic device in order to deliver dc current for powering and recharging said portable electronic device;
said power conversion module being housed within a module holder cavity of said case shell when not in use;
said USB connector being slidably mounted for extension from and retraction into said power conversion module; and
said power conversion module further including ac power mains plugs that are slidably mounted for extension and retraction independently of said USB connector.
